(19) United States
(12) Patent Application Publication
(10) Pub. No.: US 2012/0312234 A1
(43) Pub. Date: Dec. 13, 2012

(54) PROCESS GAS DIFFUSER ASSEMBLY FOR VAPOR DEPOSITION SYSTEM

(75) Inventors: Ronald NASMAN, Averill Park, NY (US); Gerrit J. LEUSINK, Saltpoint, NY (US)

(73) Assignee: TOKYO ELECTRON LIMITED, Tokyo (JP)

(21) Appl. No.: 13/158,394

(22) Filed: Jun. 11, 2011

(51) Int. Cl. C23C 16/50; H01L 21/306

(52) U.S. Cl. 118/723 R; 118/715; 156/345.29

(57) ABSTRACT

A gas diffuser assembly and vapor deposition system for use therein are described. The gas diffuser assembly includes a gas diffuser manifold configured to be coupled to a substrate processing system and arranged to introduce a process gas from a gas outlet into the substrate processing system in a direction substantially normal to a surface of a substrate to create a stagnation flow pattern over the surface. The gas diffuser manifold includes a gas inlet, a stagnation plate, and a diffusion member.

### BACKGROUND OF THE INVENTION

1. Field of Invention

The invention relates to a gas distribution system for use in electronic device manufacturing.

2. Description of Related Art

During material processing, such as semiconductor device manufacturing for production of integrated circuits (ICs), vapor deposition is a common technique to form thin films, as well as to form conformal thin films over and within complex topography, on a substrate. Vapor deposition processes can include chemical vapor deposition (CVD) and plasma enhanced CVD (PECVD). For example, in semiconductor manufacturing, such vapor deposition processes may be used for gate dielectric film formation in front-end-of-line (FEOL) operations, and low dielectric constant (low-k) or ultra-low-k, porous or non-porous, dielectric film formation and barrier/seed layer formation for metallization in back-end-of-line (BEOL) operations, as well as capacitor formation in advanced memory production.

In a CVD process, a continuous stream of film precursor vapor is introduced to a process chamber containing a substrate, wherein the composition of the film precursor has the principal atomic or molecular species found in the film to be formed on the substrate. During this continuous process, the precursor vapor is chemisorbed on the surface of the substrate while it thermally decomposes and reacts with or without the presence of an additional gaseous component that assists the reduction of the chemisorbed material, thus, leaving behind the desired film.

In a PECVD process, the CVD process further includes plasma that is utilized to alter or enhance the film deposition mechanism. For instance, plasma excitation can allow film-forming reactions to proceed at temperatures that are significantly lower than those typically required to produce a similar film by thermally excited CVD. In addition, plasma excitation may activate film-forming chemical reactions that are not energetically or kinetically favored in thermal CVD.

More recently, atomic layer deposition (ALD), a form of CVD, has emerged as a candidate for ultra-thin gate film formation in front end-of-line (FEOL) operations, as well as ultra-thin barrier layer and seed layer formation for metallization in back end-of-line (BEOL) operations. Variations of ALD include plasma-enhanced ALD, which includes plasma formation during at least a part of the ALD cycle. In ALD, two or more process gases are introduced alternatingly and sequentially in order to form a material film one monolayer at a time. Such an ALD process has proven to provide improved uniformity and control in layer thickness, as well as conformality to features on which the layer is deposited.

During vapor deposition, it is important to introduce one or more process gases, including film-forming gases, uniformly over the substrate being processed. Furthermore, in ALD systems where the deposition rate is dependent on the temporal length of each ALD cycle, the rate which the two or more process gases can be exchanged becomes an added challenge when attempting to uniformly flow one or more process gases across the substrate.

### SUMMARY OF THE INVENTION

Various embodiments relate to a gas distribution system for use in electronic device manufacturing and, in particular to a gas distribution system for use in a vapor deposition system, such as an ALD system.

According to one embodiment, a gas diffuser assembly is described. The gas diffuser assembly includes a gas diffuser manifold configured to be coupled to a substrate processing system and arranged to introduce a process gas from a gas outlet into the substrate processing system in a direction substantially normal to a surface of a substrate to create a stagnation flow pattern over the surface. The gas diffuser manifold comprises: a gas inlet for providing a flow rate of the process gas to the gas diffuser manifold, a stagnation plate located in an inlet gas plenum and configured to intersect with and force the process gas to flow radially outward, wrap around a peripheral edge of the stagnation plate, and flow radially inward, and a diffusion member located at an outlet of the inlet gas plenum and configured to diffuse the flow rate of the process gas prior to introduction into the substrate processing system, the diffusion member comprising a plurality of openings to allow the flow rate of the process gas there through.

According to another embodiment, a vapor deposition system is described. The vapor deposition system includes a process chamber having a vacuum pumping system configured to control and/or optimize a pressure in the process chamber; a substrate holder coupled to the process chamber and configured to support a substrate; and a gas distribution system having a gas diffuser manifold coupled to the process chamber and arranged to introduce a process gas from a gas outlet into the substrate processing system in a direction substantially normal to a surface of the substrate to create a stagnation flow pattern over the surface.

### BRIEF DESCRIPTION OF THE DRAWINGS

In the accompanying drawings:

FIGS. 1A through 1C show schematic representations of a deposition system according to an embodiment;

FIG. 2 provides a cross-section illustration of a gas diffuser assembly according to an embodiment;

FIG. 3 provides a cross-section illustration of a gas diffuser assembly according to another embodiment;

FIG. 4 provides a graphical illustration of an assembly view of a gas diffuser assembly according to another embodiment;

FIGS. 5A and 5B provide photographs of an assembled gas diffuser assembly according to various embodiments; and

FIGS. 6A and 6B provide exemplary data for depositing a thin film using the gas diffuser assembly depicted in FIG. 2.

### DETAILED DESCRIPTION OF SEVERAL EMBODIMENTS

In the following description, for purposes of explanation and not limitation, specific details are set forth, such as a particular geometry of a deposition system and descriptions of various components and processes used therein. However, it should be understood that the invention may be practiced in other embodiments that depart from these specific details.

Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

“Substrate” as used herein generically refers to the object being processed in accordance with the invention. The substrate may include any material portion or structure of a device, particularly a semiconductor or other electronics device, and may, for example, be a base substrate structure, such as a semiconductor wafer or a layer on or overlying a base substrate structure such as a thin film. Thus, substrate is not intended to be limited to any particular base structure, underlying layer or overlying layer, patterned or un-patterned, but rather, is contemplated to include any such layer or base structure, and any combination of layers and/or base structures. The description below may reference particular types of substrates, but this is for illustrative purposes only and not limitation.

As discussed above, during the processing of a substrate in an ALD system, the rate which two or more process gases can be exchanged poses a formidable challenge when attempting to uniformly flow the one or more process gases across the substrate. Therefore, among other design considerations, the inventors propose implementing a gas distribution system having high flow conductance to introduce a uniform flow of process gas over the substrate positioned in a deposition system having a reduced process volume, i.e., reduced residence time.

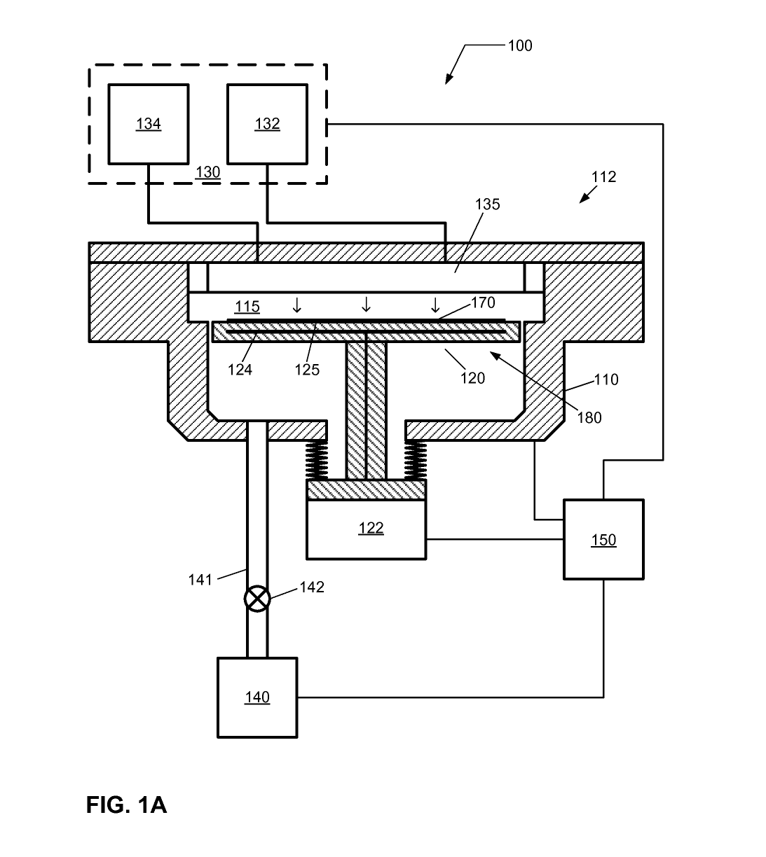

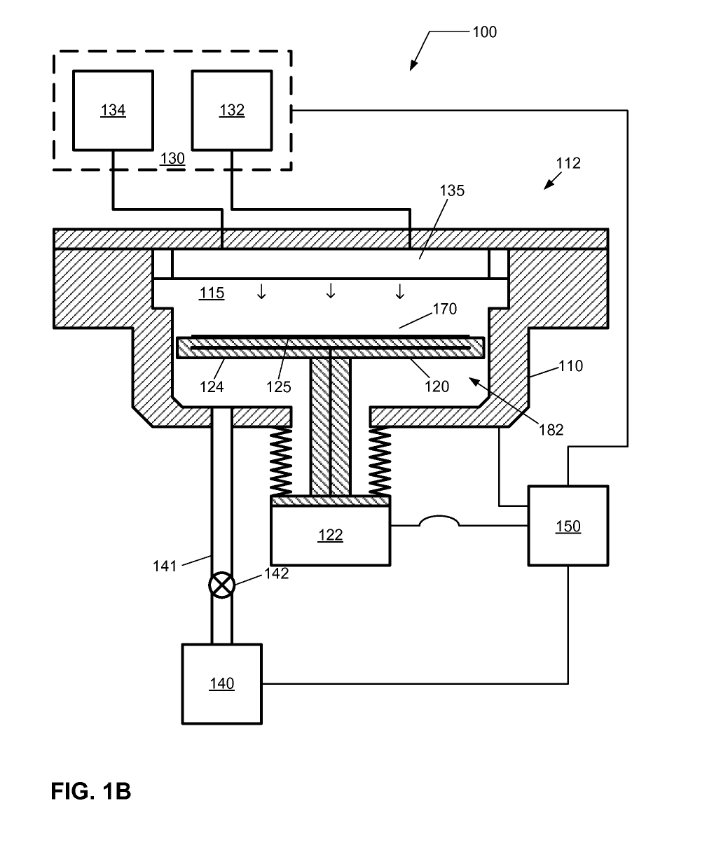

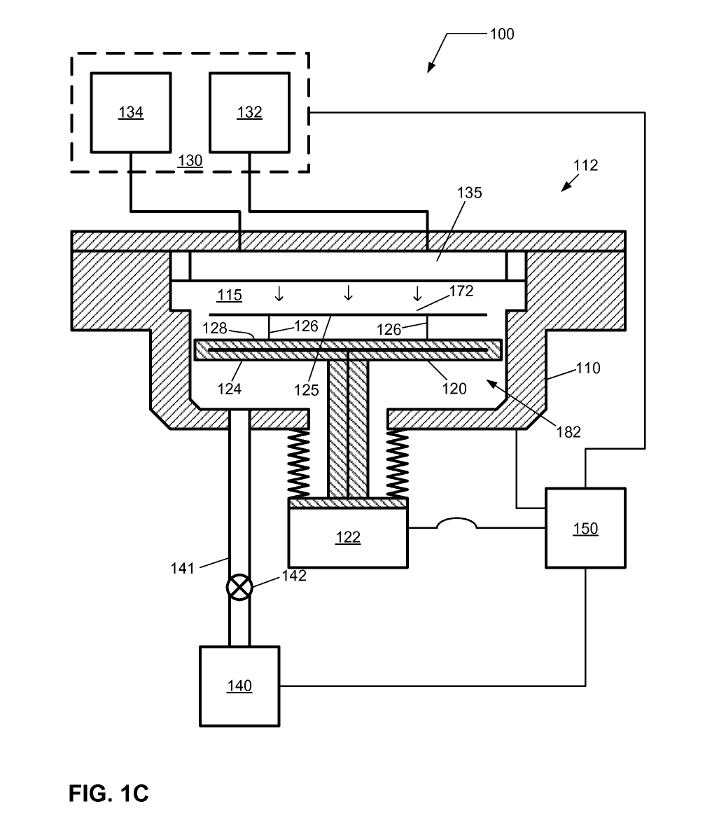

Therefore, referring now to the drawings, wherein like reference numerals designate identical or corresponding parts throughout the several views, FIGS. 1A through 1C depict a substrate processing system according to an embodiment. The substrate processing system may include a deposition system 100, such as a vapor deposition system. For example, the deposition system 100 may include an atomic layer deposition (ALD) system. Alternatively, however, deposition system 100 may include a plasma enhanced ALD (PEALD) system, a chemical vapor deposition system (CVD), a plasma enhanced CVD (PECVD) system, a filament assisted CVD (FACVD) system, a physical vapor deposition (PVD) system, an ionized PVD (iPVD) system, an atomic layer epitaxy (ALE) system), a molecular beam epitaxy (MBE) system, etc. Further, although embodiments to follow are described in the context of deposition, these embodiments are applicable to other systems and processes. For example, the substrate processing system may alternatively include an etch system, a thermal processing system, a rapid thermal processing (RTP) system, an annealing system, a rapid thermal annealing (RTA) system, a furnace, etc.

The deposition system 100 may, for example, be used to deposit metal-containing films during the metallization of inter-connect and intra-connect structures for semiconductor devices in back-end-of-line (BEOL) operations. Alternatively, the deposition system 100 may, for example, be used to deposit metal-containing films during the fabrication of gate dielectrics and/or gate electrodes in front-end-of-line (FEOL) operations.

Deposition system 100, configured, for example, to facilitate a deposition process, comprises a process chamber 110 having a substrate holder 120 configured to support a substrate 125, upon which a thin film may be formed, etched, or treated. The process chamber 110 further comprises an upper assembly 112 through which a process material and/or a cleaning material may be introduced to the process chamber 110 from a material delivery system 130. Additionally, deposition system 100 comprises a vacuum pumping system 140 coupled to the process chamber 110 and configured to evacuate process chamber 110 through one or more pumping ducts 141. Furthermore, deposition system 100 comprises a controller 150 that can be coupled to process chamber 110, substrate holder 120, material delivery system 130, and vacuum pumping system 140.

The deposition system 100 may be characterized as a stagnation flow processing system, wherein process material and/or cleaning material may be introduced through upper assembly 112 above substrate 125 in a direction substantially perpendicular to substrate 125 or substrate holder 120. For example, process material and/or cleaning material may enter above substrate 125 through a gas distribution system 135 and flow to substrate 125 in a direction substantially perpendicular with substrate 125 or substrate holder 120.

Additionally, the deposition system 100 may be configured to process 200 mm substrates, 300 mm substrates, or larger-sized substrates. In fact, it is contemplated that the substrate processing system, such as deposition system 100, may be configured to process substrates, wafers, or LCD (liquid-crystal display) panels regardless of their size, as would be appreciated by those skilled in the art.

Substrates can be introduced to process chamber 110 through a passage (not shown), and they may be lifted to and from an upper surface of substrate holder 120 via a substrate lift system 126. The substrate lift system 126 may, for example, include an array of lift pins that extend through the substrate holder 120 to the backside of substrate 125, thus, enabling vertical translation of substrate 125 between a substrate process position 170 (see FIGS. 1A and 1B) on an upper surface 128 of the substrate holder 120 and a substrate exchange position 172 (see FIG. 1C) located above the upper surface 128 of the substrate holder 120. When processing substrate 125, the substrate holder may be positioned at a process location 180 (see FIG. 1A). Alternatively, when loading or unloading substrate 125, the substrate holder may be positioned at a transfer location 182 (see FIGS. 1B and 1C).

Referring to FIG. 1A, the material delivery system 130 may include a process material supply system 132 for introducing process material to process chamber 110, and a cleaning material supply system 134 for introducing cleaning material to process chamber 110. The process material supply system 132 may be configured to provide a continuous flow, a cyclical flow, or an acyclical flow of process material to process chamber 110. Additionally, the cleaning material supply system 134 may be configured to provide a continuous flow, a cyclical flow, or an acyclical flow of cleaning material to process chamber 110.

The process material can, for example, comprise a film forming composition, such as a composition having the principal atomic or molecular species found in the film formed on substrate 125, or the process material can, for example, comprise an etchant or other treating agent. As shown in FIG. 1A, the process material may be prepared and supplied to the process chamber 110 through the upper assembly 112 using the material delivery system 130. The process material can originate as a solid phase, a liquid phase, or a gaseous phase, and it may be delivered to process chamber 110 in a gaseous phase with or without the use of an additive gas and/or a carrier gas.

For example, the process material may include one or more gases, or one or more vapors formed in one or more gases, or a mixture of two or more thereof. The process material supply system 132 can include one or more gas sources, or one or more vaporization sources, or a combination thereof. Herein vaporization refers to the transformation of a material (normally stored in a state other than a gaseous state) from a non-gaseous state to a gaseous state. Therefore, the terms “vaporization,” “sublimation” and “evaporation” are used interchangeably herein to refer to the general formation of a vapor (gas) from a solid or liquid material, regardless of whether the transformation is, for example, from solid to liquid to gas, solid to gas, or liquid to gas.

Additionally, the process material may, for example, include a purge gas. The purge gas may comprise an inert gas, such as a noble gas (i.e., helium, neon, argon, xenon, krypton), or other gas, such as an oxygen-containing gas, a nitrogen-containing gas, and/or a hydrogen-containing gas.

The cleaning material can, for example, comprise ozone. As shown in FIG. 1A, ozone may be created using an ozone gas generator and supplied to the process chamber 110 through the upper assembly 112 using the material delivery system 130. The ozone gas generator may include an H-series, P-series, C-series, or N-series ozone gas generating system commercially available from TMEIC (Toshiba Mitsubishi-Electric Industrial Systems Corporation, Tokyo, Japan). An oxygen-containing gas is supplied to the ozone gas generator, and optionally a nitrogen-containing gas is supplied to act as a catalyst. The oxygen-containing gas may include O₂, NO, NO₂, N₂O, CO, or CO₂, or any combination of two or more thereof. The nitrogen-containing gas may include N₂, NO, NO₂, N₂O, or NH₃, or any combination of two or more thereof. For example, O₂ and, optionally, N₂ may be supplied to the ozone gas generator to form ozone.

Additionally, the cleaning material may, for example, include a purge gas. The purge gas may comprise an inert gas, such as a Noble gas (i.e., helium, neon, argon, xenon, krypton), or other gas, such as an oxygen-containing gas, a nitrogen-containing gas, and/or hydrogen-containing gas.

The material delivery system 130 can include one or more material sources, one or more pressure control devices, one or more flow control devices, one or more filters, one or more valves, or one or more flow sensors. For example, the material delivery system 130 may be configured to alternatingly introduce one or more process materials, one or more cleaning materials, or one or more purge gases, or any combination of two or more thereof to process chamber 110. Furthermore, the material delivery system 130 may be configured to alternatingly introduce one or more process materials, one or more cleaning materials, or one or more purge gases, or any combination of two or more thereof through the gas distribution system 135 to the process chamber 110.

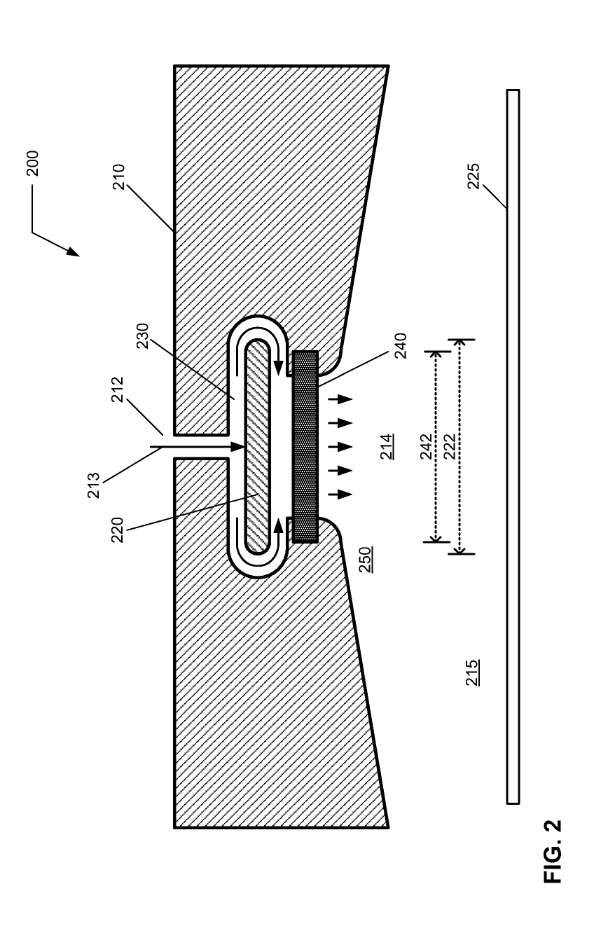

As illustrated in FIG. 2, the gas distribution system 135 may include a gas diffuser assembly 200 configured to introduce a process gas containing, for example, process material and/or cleaning material to the process chamber 110 according to an embodiment. The gas diffuser assembly 200 includes a gas diffuser manifold 210 arranged to introduce a process gas from a gas outlet 214 into a process space 215 of a substrate processing system, such as deposition system 100, in a direction substantially normal to a surface of a substrate 225 to create a stagnation flow pattern over the surface.

The gas diffuser manifold 210 comprises a gas inlet 212 for providing a flow rate of the process gas 213 to the gas diffuser manifold 210, a stagnation plate 220 located in an inlet gas plenum 230 and configured to intersect with and force the process gas 213 to flow radially outward, wrap around a peripheral edge of the stagnation plate 220, and flow radially inward, and a diffusion member 240 located at an outlet of the inlet gas plenum and configured to diffuse the flow rate of the process gas 213 prior to introduction into the process space 215, wherein the diffusion member 240 comprises a plurality of openings to allow the flow rate of the process gas 213 there through.

The diffusion member 240 may include a porous foam member, a perforated member, a plate-like member, a mesh-like member, or a screen-like member, or any combination of two or more thereof. For example, the diffusion member 240 may include a porous foam member having a porosity ranging from about 5 pores per inch to about 200 pores per inch. Additionally, for example, the diffusion member 240 may include a porous foam member having a porosity ranging from about 10 pores per inch to about 100 pores per inch. Additionally yet, for example, the diffusion member 240 may include a porous foam member having a porosity ranging from about 10 pores per inch to about 60 pores per inch.

As shown in FIG. 2, the stagnation plate 220 and the diffusion member 240 are centered on an axis of the gas inlet 212. Further, a first lateral dimension 222 of the stagnation plate 220 may exceed a second lateral dimension 242 of the diffusion member 240. For example, the stagnation plate 220 and the diffusion member 240 may each include a circular plate or disc, wherein a first diameter of the stagnation plate 220 exceeds a second diameter of the diffusion member 240. As described above, the flow of the process gas 213 is forced to flow radially outward, wrap around a peripheral edge of the stagnation plate 220, and flow radially inward.

For example, the second diameter of the diffusion member 240, through which the flow of the process gas 213 passes to substrate 225, may range from about 5% to about 50% the diameter of substrate 225 being processed. Additionally, for example, the second diameter of the diffusion member 240 may range from about 10% to about 30% the diameter of substrate 225 being processed. Additionally yet, for example, the second diameter of the diffusion member 240 may range from about 15% to about 20% the diameter of substrate 225 being processed.

By designing the first lateral dimension 222 of the stagnation plate 220 to be larger than the second lateral dimension 242 of the diffusion member 240, the flow of the process gas 213, when flowing radially inward, may flow substantially parallel to a front surface of the diffusion member 240 facing the inlet gas plenum 230 before turning to flow through the diffusion member 240. Further, the exterior portion of the inlet gas plenum 230 and/or the peripheral edge of the stagnation plate 220 may be shaped, e.g., may be designed to possess smooth, round surfaces, to allow the flow of process gas 213 to flow around the stagnation plate 220 without substantial loss or separation.

As shown in FIG. 2, the gas diffuser assembly 200 may also include an outlet gas plenum 250 located at an outlet of the diffusion member 240. The outlet gas plenum 250 may include a cylindrically shaped plenum, a conically shaped plenum, or a plenum of arbitrary shape.

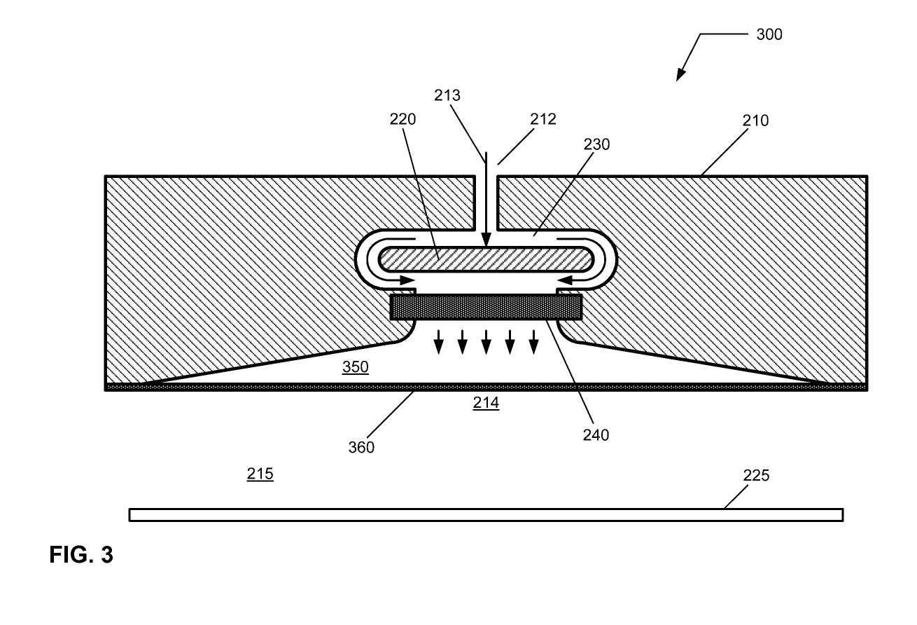

According to another embodiment, as shown in FIG. 3, a gas diffuser assembly 300 may include an outlet gas plenum 350 located at an outlet of the diffusion member 240, and an outlet gas distribution plate 360 located at an outlet of the outlet gas plenum 350. The outlet gas plenum 350 may include a cylindrically shaped plenum, a conically shaped plenum, or a plenum of arbitrary shape. The outlet gas distribution plate 360 may include a porous foam member, a perforated member, a plate-like member, a mesh-like member, or a screen-like member, or any combination of two or more thereof.

The gas diffuser assembly (200, 300) may be designed to have a flow conductance from the gas inlet 212 to the gas outlet 214 that exceeds 10 liters per second. Alternatively, the gas diffuser assembly (200, 300) may be designed to have a flow conductance from the gas inlet 212 to the gas outlet 214 that exceeds 20 liters per second.

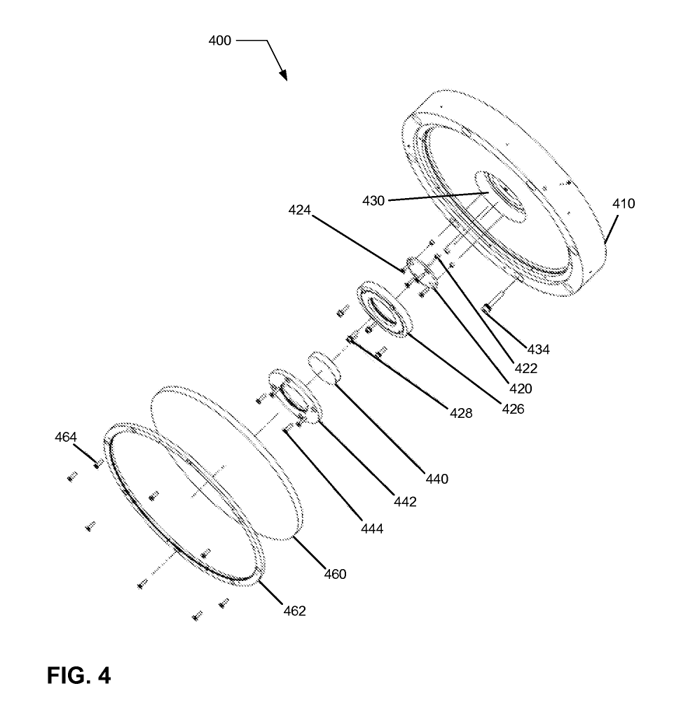

Referring now to FIG. 4, an assembly view of a gas diffuser assembly 400 is provided according to another embodiment. The gas diffuser assembly 400 includes a gas diffuser manifold 410 having a gas inlet (not shown) and an inlet gas plenum 430. The gas diffuser manifold 410 may be attached to a substrate processing system, such as deposition system 100 in FIGS. 1A through 1C, using fasteners 434. The gas diffuser assembly 400 further includes a stagnation plate 420 configured to be positioned within the inlet gas plenum 430, an inlet gas plenum ring 426 configured to attach to the gas diffuser manifold 410 and further define inlet gas plenum 430, a gas diffusion member 440, and a clamp ring 442 configured to couple with the inlet gas plenum ring 426 and securely affix the diffusion member 440 there between. The stagnation plate 420 is attached to the gas diffuser manifold 410 using fasteners 424 and spaced away from the gas inlet using spacers 422. Additionally, the clamp ring 442 is attached to the inlet gas plenum ring 426 using fasteners 444.

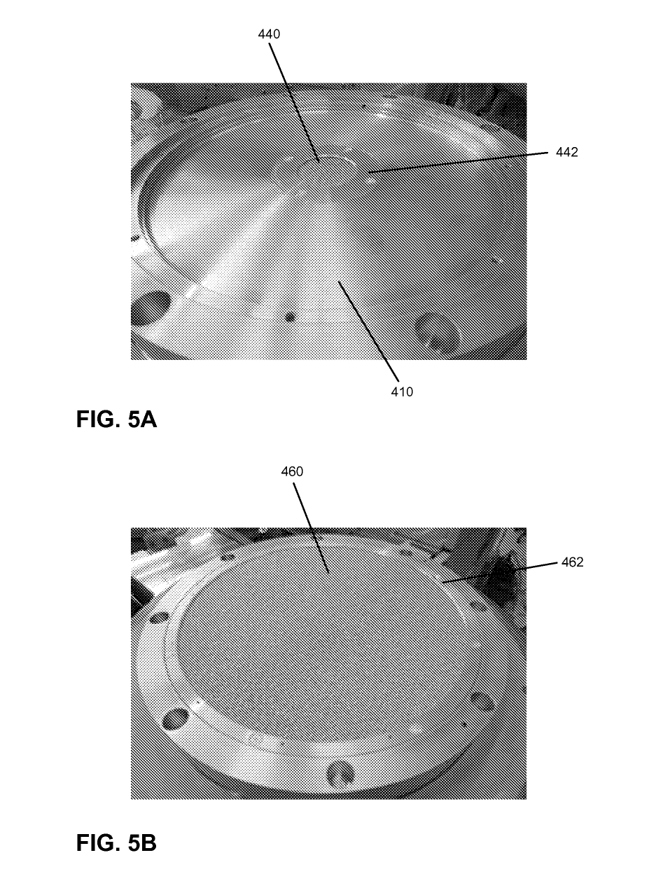

Optionally, the gas diffuser assembly 400 may include an outlet gas distribution plate 460 that may be attached to the gas diffuser manifold 410 using plate ring 462 and fasteners 464. A bottom photograph of the gas diffuser assembly 400 without the outlet gas distribution plate 460 is provided in FIG. 5A, and a bottom photograph of the gas diffuser assembly 400 with the outlet gas distribution plate 460 is provided in FIG. 5B.

Referring again to FIG. 1A, the substrate holder 120 comprises one or more temperature control elements 124 that may be configured for heating, or cooling, or both heating and cooling. Further, the one or more temperature control elements 124 may be arranged in more than one separately controlled temperature zones. The substrate holder 120 may have two thermal zones, including an inner zone and an outer zone. The temperatures of the zones may be controlled by heating or cooling the substrate holder thermal zones separately.

According to another example, the one or more temperature control elements 124 may include a substrate cooling element embedded beneath the surface of or within the substrate holder 120. For instance, the substrate cooling element may include a re-circulating fluid flow that receives heat from substrate holder 120 and transfers heat to a heat exchanger system. According to yet another example, the one or more temperature control elements 124 may include one or more thermo-electric devices.

Additionally, the substrate holder 120 may optionally comprise a substrate clamping system (e.g., electrical or mechanical clamping system) to clamp the substrate 125 to the upper surface of substrate holder 120. For example, substrate holder 120 may include an electrostatic chuck (ESC).

Furthermore, the substrate holder 120 may optionally facilitate the delivery of heat transfer gas to the back-side of substrate 125 via a backside gas supply system to improve the gas-gap thermal conductance between substrate 125 and substrate holder 120. Such a system can be utilized when temperature control of the substrate is required at elevated or reduced temperatures. For example, the backside gas system can comprise a two-zone gas distribution system, wherein the backside gas (e.g., helium) pressure can be independently varied between the center and the edge of substrate 125.

Although not shown, process chamber 110 may also include one or more temperature control elements that may be configured for heating, or cooling, or both heating and cooling. For example, the one or more temperature control elements may include a wall heating element configured to elevate the temperature of the process chamber 110 in order to reduce condensation, which may or may not cause film formation on surfaces of the process chamber 110, and the accumulation of residue. Furthermore, the upper assembly 112 of process chamber 110 may also include one or more temperature control elements that may be configured for heating, or cooling, or both heating and cooling. For example, the one or more temperature control elements may include a gas/vapor delivery heating element configured to elevate the temperature of the surfaces in contact with process material, cleaning material, or purge gases, or a combination thereof introduced to process chamber 110.

Acting on program instructions, a temperature control system, or controller 150, or both may be configured to monitor, adjust, and/or control the temperature of substrate holder 120. For example, the substrate holder 120 may be operated at a temperature ranging up to approximately 600 degrees C. Alternatively, for example, the substrate holder 120 may be operated at a temperature ranging up to approximately 500 degrees C. Alternatively, for example, the substrate holder 120 may be operated at a temperature ranging from approximately 200 degrees C. to approximately 400 degrees C.

Additionally, also acting on program instructions, a temperature control system, or controller 150, or both may be configured to monitor, adjust, and/or control the temperature of process chamber 110. For example, the process chamber 110 may be operated at a temperature ranging up to approximately 400 degrees C. Alternatively, for example, the process chamber 110 may be operated at a temperature ranging up to approximately 300 degrees C. Alternatively, for example, the process chamber 110 may be operated at a temperature ranging from approximately 50 degrees C. to approximately 200 degrees C.

The temperature control system, or controller 150, or both may use one or more temperature measuring devices to monitor one or more temperatures, such as a temperature of substrate 125, a temperature of substrate holder 120, a temperature of process chamber 110, etc.

As an example, the temperature measuring device may include an optical fiber thermometer, an optical pyrometer, a band-edge temperature measurement system as described in pending U.S. patent application Ser. No. 10/168,544, filed on Jul. 2, 2002 and now issued as U.S. Pat. No. 6,891,124, the contents of which are incorporated herein by reference in their entirety, or a thermocouple such as a K-type thermocouple. Examples of optical thermometers include: an optical fiber thermometer commercially available from Advanced Energies, Inc., Model No. OR2000F; an optical fiber thermometer commercially available from Luxtron Corporation, Model No. M600; or an optical fiber thermometer commercially available from Takaoka Electric Mfg., Model No. FT-1420.

Referring still to FIG. 1A, the vacuum pumping system 140 may include a dry vacuum pump, such as a turbo-molecular vacuum pump (TMP) or a cryogenic pump capable of a pumping speed up to about 5000 liters per second (and greater), coupled to process chamber 110 and configured to control and/or optimize a pressure in process chamber 110 via pumping through one or more pumping ducts 141. The vacuum pumping system 140 may comprise one or more vacuum valves 142 to control the pumping speed delivered to process chamber 110. Furthermore, the vacuum pumping system 140 may comprise a pressure control system for monitoring, adjusting, optimizing, and/or controlling a pressure in process chamber 110.

Referring again to FIG. 1A, controller 150 can comprise a microprocessor, memory, and a digital I/O port capable of generating control voltages sufficient to communicate and activate inputs to the substrate processing system, such as deposition system 100, as well as monitor outputs from the substrate processing system, such as deposition system 100. Moreover, the controller 150 may be coupled to and may exchange information with the process chamber 110, substrate holder 120, material delivery system 130, and vacuum pumping system 140. For example, a program stored in the memory may be utilized to activate the inputs to the aforementioned components of the substrate processing system, such as deposition system 100, according to a process recipe in order to perform a deposition process, an etching process, a treatment process, and/or a cleaning process.

However, controller 150 may be configured for any number of processing elements (110, 120, 130, 140), and the controller 150 can collect, provide, process, store, and display data from processing elements. Controller 150 can comprise a number of applications for controlling one or more of the processing elements. For example, controller 150 may include a graphic user interface (GUI) component (not shown) that can provide easy to use interfaces that enable a user to monitor and/or control one or more processing elements.

Alternately, or in addition, controller 150 may be coupled to one or more additional controllers/computers (not shown), and controller 150 may obtain setup and/or configuration information from an additional controller/computer.

Controller 150 or portions of controller 150 may be locally located relative to the substrate processing system, such as deposition system 100, and/or may be remotely located relative to the substrate processing system, such as deposition system 100. For example, the controller 150 may exchange data with the substrate processing system, such as deposition system 100, using at least one of a direct connection, an intranet, the Internet and a wireless connection. The controller 150 may be coupled to an intranet at, for example, a customer site (i.e., a device maker, etc.), or it may be coupled to an intranet at, for example, a vendor site (i.e., an equipment manufacturer). Additionally, for example, the controller 150 may be coupled to the Internet. Furthermore, another computer (i.e., controller, server, etc.) may access, for example, the controller 150 to exchange data via at least one of a direct connection, an intranet, and the Internet. As also would be appreciated by those skilled in the art, the controller 150 may exchange data with the substrate processing system, such as deposition system 100, via a wireless connection.

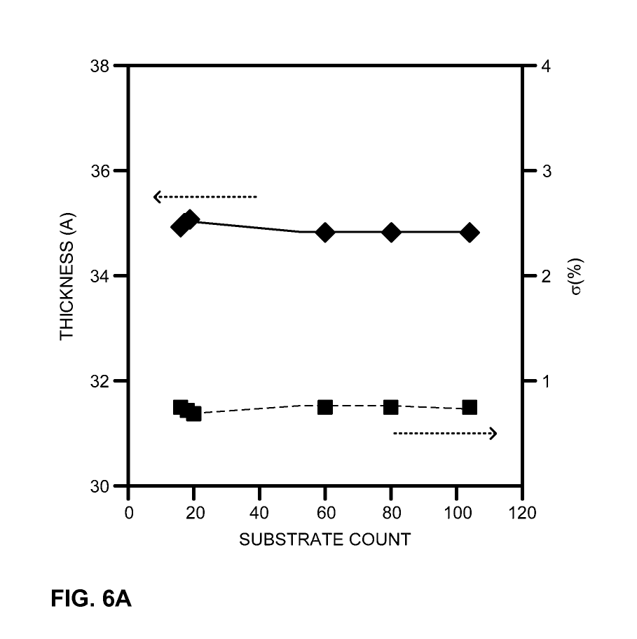

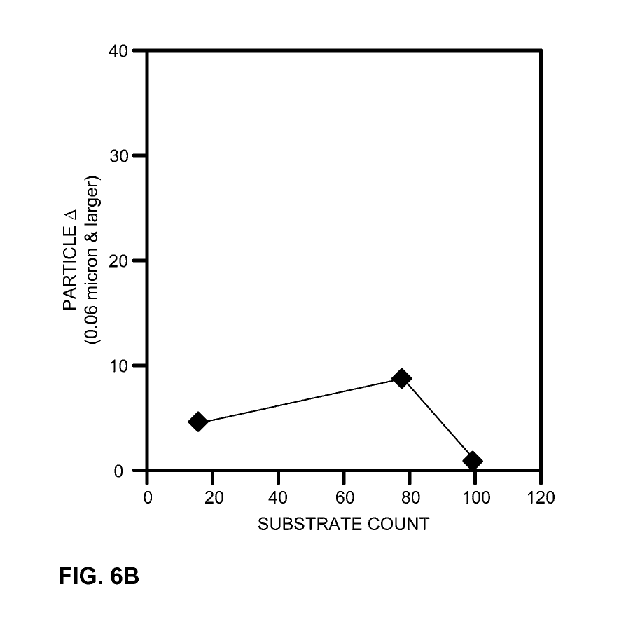

In an example, hafnium oxide (HfO₂) films have been deposited using a deposition system, such as deposition system 100 depicted in FIGS. 1A through 1C, using a gas diffuser assembly such as the one depicted in FIG. 2. The deposition process is an ALD process having 35 cycles, wherein each cycle includes: (1) an introduction of Hf-containing precursor; (2) a first gas purge; (3) an introduction of an oxidizer; and (4) a second gas purge. FIG. 6A provides the thickness of the thin film (Angstrom, A) (solid line, solid diamonds) and the standard deviation (σ, %) (dashed line, solid squares) as a function of substrate count. Up to and exceeding 100 substrates, the thin film is repeatedly produced with a thickness of about 35 A, and a standard deviation across a 300 mm substrate of less than 1%. Furthermore, FIG. 6B provides the particle delta (Δ) for 0.06 micron particles and larger added to each substrate as a result of the deposition process, i.e., difference in particle count between immediately following the deposition process and immediately preceding the deposition process.

Although only certain embodiments of this invention have been described in detail above, those skilled in the art will readily appreciate that many modifications are possible in the embodiments without materially departing from the novel teachings and advantages of this invention. Accordingly, all such modifications are intended to be included within the scope of this invention.

1. A gas diffuser assembly for introducing a process gas into a substrate processing system, comprising:
a gas diffuser manifold configured to be coupled to a substrate processing system and arranged to introduce a process gas from a gas outlet into said substrate processing system in a direction substantially normal to a surface of a substrate to create a stagnation flow pattern over said surface, said gas diffuser manifold comprises:
a gas inlet for providing a flow rate of said process gas to said gas diffuser manifold,
a stagnation plate located in an inlet gas plenum and configured to intersect with and force said process gas to flow radially outward, wrap around a peripheral edge of said stagnation plate, and flow radially inward, and
a diffusion member located at an outlet of said inlet gas plenum and configured to diffuse said flow rate of said process gas prior to introduction into said substrate processing system, said diffusion member comprising a plurality of openings to allow said flow rate of said process gas there through.

2. The gas diffuser assembly of claim 1, wherein said substrate processing system includes a vapor deposition system or an etching system.

3. The gas diffuser assembly of claim 1, wherein said diffusion member comprises a porous foam member, a perforated member, a plate-like member, a mesh-like member, or a screen-like member, or any combination of two or more thereof.

4. The gas diffuser assembly of claim 3, wherein said porous foam member comprises a porosity ranging from about 5 pores per inch to about 200 pores per inch.

5. The gas diffuser assembly of claim 3, wherein said porous foam member comprises a porosity ranging from about 10 pores per inch to about 100 pores per inch.

6. The gas diffuser assembly of claim 3, wherein said porous foam member comprises a porosity ranging from about 10 pores per inch to about 60 pores per inch.

7. The gas diffuser assembly of claim 1, wherein said stagnation plate and said diffusion member are centered on an axis of said gas inlet.

8. The gas diffuser assembly of claim 1, wherein a first lateral dimension of said stagnation plate exceeds a second lateral dimension of said diffusion member.

9. The gas diffuser assembly of claim 1, further comprising:
an outlet gas plenum located at an outlet of said diffusion member.

10. The gas diffuser assembly of claim 9, wherein said outlet gas plenum comprises a conically shaped plenum.

11. The gas diffuser assembly of claim 9, further comprising:
an outlet gas distribution plate located at an outlet of said outlet gas plenum.

12. The gas diffuser assembly of claim 11, wherein said outlet gas distribution plate comprises a porous foam member, a perforated member, a plate-like member, a mesh-like member, or a screen-like member, or any combination of two or more thereof.

13. The gas diffuser assembly of claim 1, wherein a flow conductance of said gas diffuser assembly from said gas inlet to said gas outlet exceeds about 200 liters per second.

14. The gas diffuser assembly of claim 1, wherein a flow conductance of said gas diffuser assembly from said gas inlet to said gas outlet exceeds about 500 liters per second.

15. A deposition system for depositing a thin film on a substrate, comprising:
a process chamber having a vacuum pumping system configured to control and/or optimize a pressure in said process chamber;
a substrate holder coupled to said process chamber and configured to support a substrate; and
a gas distribution system having a gas diffuser manifold coupled to said process chamber and arranged to introduce a process gas from a gas outlet into said substrate processing system in a direction substantially normal to a surface of said substrate to create a stagnation flow pattern over said surface, said gas diffuser manifold comprises:
a gas inlet for providing a flow rate of said process gas to said gas diffuser manifold,
a stagnation plate located in an inlet gas plenum and configured to intersect with and force said process gas to flow radially outward, wrap around a peripheral edge of said stagnation plate, and flow radially inward, and
a diffusion member located at an outlet of said inlet gas plenum and configured to diffuse said flow rate of said process gas prior to introduction into said substrate processing system, said diffusion member comprising a plurality of openings to allow said flow rate of said process gas there through.

16. The deposition system of claim 15, wherein said diffusion member comprises a porous foam member, a perforated member, a plate-like member, a mesh-like member, or a screen-like member, or any combination of two or more thereof.

17. The deposition system of claim 15, wherein said substrate holder comprises one or more temperature control elements configured to control a temperature of said substrate.

18. The deposition system of claim 15, further comprising:
a material delivery system coupled to said gas distribution system and configured to supply said gas distribution system with said flow of said process gas.

19. The deposition system of claim 18, wherein said material delivery system is configured to alternatingly and sequentially introduce two or more flows of process gas to said gas distribution system.

20. The deposition system of claim 15, further comprising:
a plasma generation system coupled to said process chamber and configured to excite plasma in said process chamber.
